(19) United States
(12) Patent Application Publication
(10) Pub. No.: US 2024/0347471 A1
(43) Pub. Date: Oct. 17, 2024

(54) WAFER COMPOSITE STRUCTURE AND METHOD FOR MAKING THE SAME, AND PATTERN MAKING SYSTEM

(71) Applicant: Prosemi Co., Ltd., Tainen City (TW)

(72) Inventor: Wen-Shian CHEN, Kaohsiung City (TW)

(21) Appl. No.: 18/631,499

(22) Filed: Apr. 10, 2024

(30) Foreign Application Priority Data
Apr. 11, 2023 (TW) 112113512

(51) Int. Cl. H01L 23/544; H01L 21/66

(52) U.S. Cl. CPC H01L 23/544; H01L 22/12; H01L 2223/54426

(57) ABSTRACT

A wafer composite structure includes a wafer including a wafer alignment pattern, and a double-sided-patterned substrate including a base substrate that has a front surface and a back surface, a front alignment pattern unit, and a back alignment pattern unit. The front surface is attached with the wafer, and the front alignment pattern unit is aligned with the wafer alignment pattern. A method for making the wafer composite structure includes: providing a to-be-treated substrate; forming the back alignment pattern unit on the back surface; and aligning the front alignment pattern unit with the wafer alignment pattern and attaching the wafer to the front substrate surface of the base substrate. A pattern making system includes an optical inspection device, a pattern making device configured to form the back alignment pattern unit, and an adjustment device connected to the optical inspection device and the pattern making device.

### CROSS-REFERENCE TO RELATED APPLICATION

This application claims priority to Taiwanese Invention Patent application No. 112113512, filed on Apr. 11 2023, which is incorporated by reference herein in its entirety.

### FIELD

The disclosure relates to a wafer composite structure, a method of making the wafer composite structure, and a pattern making system.

### BACKGROUND

Wafer-to-wafer bonding or chip-to-wafer bonding is an important process in semiconductor fabrication. For example, during a conventional wafer-to-wafer bonding process in which front sides of two wafers are bonded together, an optical inspection equipment employing infrared (IR) or far infrared (FIR) light is used to detect alignment patterns formed on the front sides of the two wafers position the two wafers before bonding. This is done so that the wafers can be properly aligned. More specifically, the IR or FIR light must pass through the wafer from a back side of the wafer to detect the alignment pattern on the front side of the wafer so as to generate a positioning information, and the positioning information is then used as a reference for aligning the two wafers.

However, several factors may affect alignment accuracy in the conventional process. Specifically, the thickness and the material of the wafer may affect the alignment accuracy since the IR light must pass through the wafer to obtain the positioning information. Additionally, maximum resolution of the optical inspection equipment is also a factor that limits alignment precision in the conventional process. There is increasing concern in the field in regards to alignment accuracy, since advancement in semiconductor technology has lead to shrinking in the size of semiconductor components, and thus reduction in the size of circuitry. Reduction in circuit sizes necessitates the employment of more complex circuit designs which requires more precision during alignment, and thus, effects on the electrical characteristics of the semiconductor component as caused by misalignment of two wafers would be amplified.

### SUMMARY

Therefore, an object of the disclosure is to provide a wafer-composite structure, a method for making the wafer composite structure, and a pattern making system that can alleviate at least one of the drawbacks of the prior art.

According to a first aspect of the disclosure, the wafer composite structure includes a wafer, and a double-sided-patterned substrate. The wafer includes a wafer alignment pattern. The double-sided-patterned substrate includes a base substrate, a circuit pattern unit, a front alignment pattern unit, and a back alignment pattern unit. The base substrate has a front surface, and a back surface opposite to the front surface. The circuit pattern unit is located on the front surface. The front alignment pattern unit is located on the front surface. The back alignment pattern unit is located on the back surface, and has a position corresponding according to a predetermined relation relative to a position of the front alignment pattern unit. The front surface of the base substrate of the double-sided-patterned substrate is attached with the wafer, and the front alignment pattern unit or the back alignment pattern unit is aligned with the wafer alignment pattern of the wafer.

According to a second aspect of the disclosure, the method for making a wafer composite structure includes a) providing a to-be-treated substrate that includes a base substrate having a front surface and a back surface opposite to the front surface, a circuit pattern unit located on the front surface, and a front alignment pattern unit located on the front surface; b) forming a back alignment pattern unit on the back surface of the base substrate, the back alignment pattern unit being formed in a predetermined position that corresponds according to a predetermined relation relative to the front alignment pattern unit; c) aligning the front alignment pattern unit with a wafer alignment pattern of a wafer using the positon of the back alignment pattern unit as a reference, and attaching the wafer to the front substrate surface of the base substrate.

According to a third aspect of the disclosure, the pattern making system is adapted to form a back alignment pattern unit on a to-be-treated substrate. The to-be-treated substrate includes a base substrate and a front alignment pattern unit. The base substrate has a front surface, and a back surface opposite to the front surface. The front alignment pattern unit is on the front surface. The back alignment pattern unit is to be formed on the back surface of the base substrate of the to-be-treated substrate. The pattern making system includes an optical inspection device, a pattern making device, and an adjustment device. The optical inspection device is adapted to be disposed on the front surface of the base substrate of the to-be-treated substrate, and has a first alignment pattern that has a geometric center. When the geometric center of the first alignment pattern overlaps with a geometric center of the back alignment pattern unit, a location signal of the front alignment pattern unit is generated. The pattern making device is adapted to be disposed on the back surface of the to-be-treated substrate, is signally connected to the optical inspection device, and configured to form the back alignment pattern unit on the back surface of the base substrate of the to-be-treated substrate based on the location signal. The back alignment pattern unit and the front alignment pattern unit correspond in position to each other according to a predetermined relation. The adjustment device is connected to the optical inspection device and the pattern making device to allow adjustment of positions of the optical inspection device and the pattern making device relative to the to-be-treated substrate. The adjustment device has a securing member, and two adjustment arms that extends from the securing member, and that are respectively connected to the optical inspection device and the pattern making device.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is an exploded schematic perspective view illustrating an embodiment of a wafer composite structure according to the present disclosure.

FIG. 2 is a schematic top view illustrating relative positioning between a back alignment pattern unit and a front alignment pattern unit.

FIG. 3 is a fragmentary schematic perspective view illustrating a first embodiment of a pattern making system according to the present disclosure.

FIG. 4 is a schematic top view illustrating relative positioning of a first alignment pattern and a second alignment pattern with the front alignment pattern.

FIG. 5 is a block diagram illustrating an embodiment of a method for making the wafer composite structure.

FIG. 6 is a schematic top view illustrating a positioning of a calibration pattern relative to the front alignment pattern unit.

FIG. 7 is a schematic top view illustrating a positioning of another calibration pattern relative to the front alignment pattern unit.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

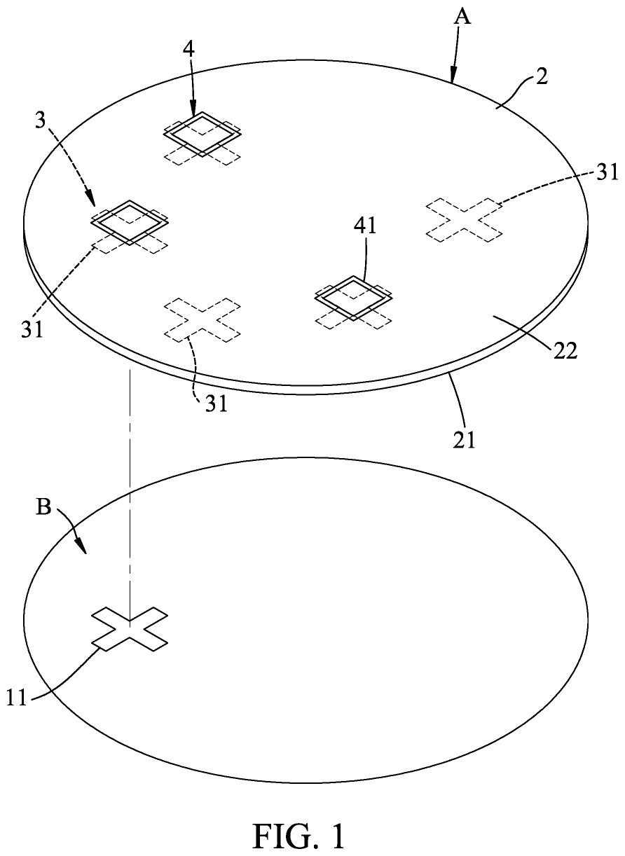

Referring to FIG. 1, an embodiment of a wafer composite structure according to the present disclosure includes a wafer (B), and a double-sided-patterned substrate (A). The wafer (B) includes a wafer alignment pattern 11. The double-side-patterned substrate (A) includes a base substrate 2, a circuit pattern unit (not shown), a front alignment pattern unit 3, and a back alignment pattern unit 4. The base substrate 2 has a front surface 21 and a back surface 22 opposite to the front surface 21. The circuit pattern unit is located on the front surface 21. The front alignment pattern unit 3 is located on the front surface 21. The back alignment pattern unit 4 is located on the back surface 22. The double-sided-patterned substrate (A) is shown with the front surface 21 of the base substrate facing down in FIG. 1. In this embodiment, the double-sided-patterned substrate (A) is made of a semiconductor material, and the circuit pattern unit located on the front surface 21 of the base substrate 2 is fabricated via a patterning process. The circuit pattern unit may be composed of trenches or electrical wiring etc. The wafer (B) is attached with the front surface 21 of the base substrate 2 of the double-sided-patterned substrate (A). The front alignment pattern unit 3 is aligned with the wafer alignment pattern 11 of the wafer (B). In other embodiments, the back alignment pattern unit 4 is aligned with the wafer alignment pattern 11 of the wafer (B).

In other embodiments, the base substrate 2 may be a dielectric substrate, a printed circuit board (PCB), or a metallic substrate. In other embodiments, the base substrate 2 may be a laminated circuit board having a dielectric layer, a metallic layer, or an oxide layer. However, the aforesaid is not a limitation of the present disclosure.

The front alignment pattern unit 3 is fabricated via a patterning process, and is located on the front surface 21 of the base substrate 2. In this embodiment, the circuit pattern unit and the front alignment pattern unit 3 are located on the same surface, i.e., the front surface 21 of the base substrate 2. The front alignment pattern unit 3 has at least one front alignment pattern 31. In this embodiment, the front alignment pattern unit 3 is made from a photoresist material and is formed via a patterning process on the front surface 21.

The back alignment pattern unit 4 is formed on the back surface 22 of the base substrate 2, and has at least one back alignment pattern 41. The back alignment pattern unit 4 has a position that corresponds according to a predetermined relation relative to a position of the front alignment pattern unit 3. For example, in the embodiment shown in FIG. 1, the predetermined relation is one where a geometric center of the back alignment pattern unit 4 overlaps with a geometric center of the front alignment pattern unit 3. However, in other embodiments, the predetermined relation may be one where the back alignment pattern unit 4 and the front alignment pattern unit 3 are spaced apart along a particular direction by a predetermined amount. In this embodiment, the back alignment pattern unit 4 is made by an ablation procedure, and is indented from the back surface 22 of the base substrate 2. More specifically, the back alignment pattern unit 4 may be formed via etching or laser ablation from the back surface 22 of the base substrate 2; however, this is not a limitation of the disclosure.

In other embodiments, the back alignment pattern unit 4 may be formed on the back surface 22 of the base substrate 2 via a deposition process such as 3D printing or atomic layer deposition (ALD).

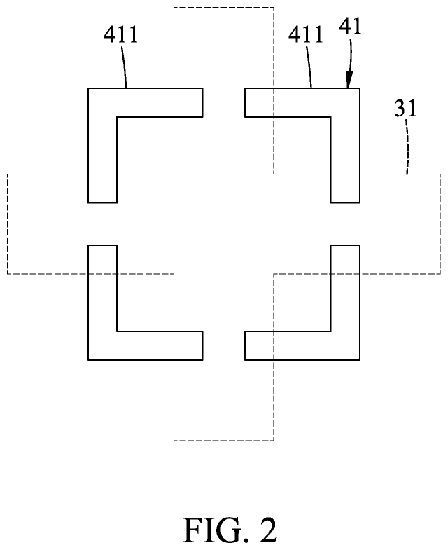

The shape and pattern of the front alignment pattern 31 may be the same as or different from the back alignment pattern 41, and the examples of the front alignment pattern 31 and the back alignment pattern 41 as illustrated in FIG. 1 are but one exemplary manifestation. Referring to FIG. 2, in some embodiments, the back alignment pattern 41 may be composed of four L-shaped pattern fragments 411, and the front alignment pattern 31 has a cruciform shape. A geometric center of the 4 L-shaped pattern fragments 411 may overlap with a geometric center of the cruciform front alignment pattern 31.

In certain embodiments, the front alignment pattern unit 3 includes a plurality of the front alignment pattern 31, and the back alignment pattern unit 4 includes a plurality of the back alignment pattern 41. In some embodiments, the back alignment patterns 41 may correspond in position to some of the front alignment patterns 31. In some embodiments, a geometric center of one of the back alignment patterns 41 may be situated in a predetermined position that corresponds according to a predetermined relation relative to a position of a geometric center of a corresponding one of the front alignment patterns 31. Furthermore, in some embodiments, the geometric center of the one of the back alignment patterns 41 may overlap with the geometric center of the corresponding one of the front alignment patterns 31. It should be noted that, it is sufficient that only some of the back alignment patterns 41 each correspond in position to one front alignment pattern 31, and not necessary for every one of the back alignment patterns 41 to correspond in position to a respective one of the front alignment patterns 31.

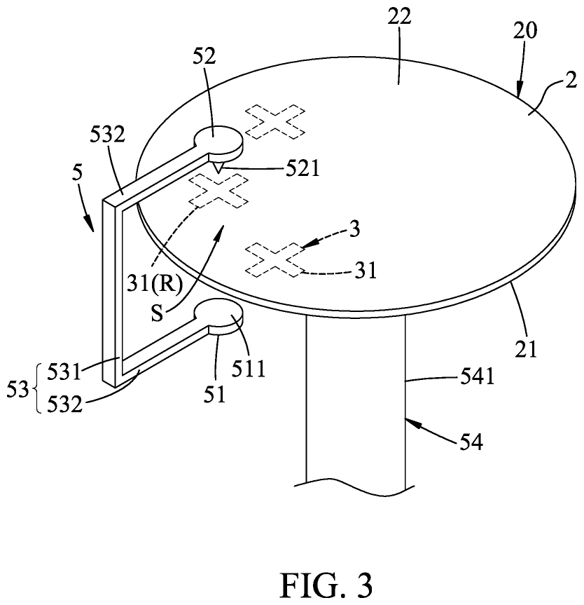

Referring to FIGS. 1 to 3, a pattern making system 5 is used in a method for making the embodiment of the wafer composite structure. The pattern making system 5 is adapted to form the back alignment pattern unit 4 on a to-be-treated substrate 20. The to-be-treated substrate 20 includes the base substrate 2 that has the front surface 21 and the back surface 22 that is opposite to the front surface 22, and the front alignment pattern unit 3 on the front surface 21. The back alignment pattern unit 4 is to be formed on the back surface 22 of the base substrate 2. In this embodiment, the base substrate 2 is a semiconductor substrate.

The pattern making system 5 includes an optical inspection device 51, a pattern making device 52, an adjustment device 53, and a securing device 54.

The optical inspection device 51 is adapted to be disposed on the front surface 21 of the base substrate 2 of the to-be-treated substrate 20, and has an optical reading member 511, and a first alignment pattern 512 that may be used as a positioning reference for the optical reading member 511. The optical inspection device 51 may be an automated optical inspection (AOI) instrument; however, this is not a limitation of the disclosure. The optical reading member 511 may capture images or use diffraction positioning to obtain a location of the front alignment pattern unit 3 and generate a location signal.

The pattern making device 52 is adapted to be disposed on the back surface 22 of the base substrate 2 of the to-be-treated substrate 20, and is signally connected to the optical inspection device 51. The pattern making device 52 includes a pattern making member 521, and a second alignment pattern 522 that may be used as a positioning reference for the pattern making member 521. The pattern making member 521 of the pattern making device 52 is configured to form the back alignment pattern unit 4 on the back surface 22 of the base substrate 2 of the to-be-treated substrate 20 based on the location signal. The front alignment pattern unit 3 at the front surface 21 of the base substrate 2 and the back alignment pattern unit 4 thus formed by the pattern making device 52 correspond in position to each other according to a predetermined relation. The pattern making member 521 may form the back alignment pattern unit 4 via deposition or laser ablation. The pattern making member 521 may be one of a 3D printer, a laser additive manufacturing machine, a laser ablation machine, an electron beam machine, and an ion beam machine. However, this is not a limitation of the disclosure.

Additionally, it should be noted that the first alignment pattern 512 and the second alignment pattern 522 are not limited to a particular shape or pattern and may be a physical object or a virtual projection. In practice, either one of the first alignment pattern 512 and the second alignment pattern 522 may be used as a positioning reference for alignment. For example, a geometric center of one of the first alignment pattern 512 and the second alignment pattern 522 may be used to overlap with a geometric center of the front alignment pattern unit 3. The shape or pattern of the first alignment pattern 512 and the second alignment pattern 522 may be respectively the same as the shape or pattern of the front alignment pattern 31 and the back alignment pattern 41 as shown in FIGS. 1 and 2.

The adjustment device 53 is connected to the optical inspection device 51 and the pattern making device 52 to allow adjustment of positions of the optical inspection device 51 and the pattern making device 52 relative to the to-be-treated substrate 20. The adjustment device 53 has a securing member 531, and two adjustment arms 532 that extend from the securing member 531 and that are respectively connected to the optical inspection device 51 and the pattern making device 52. Each of the adjustment arms 532 have a length that is adjustable. The to-be-treated substrate 20 is disposed between the two adjustment arms 532 so that the optical inspection device 51 and the pattern making device 52 that are respectively connected to the two adjustment arms 532 are respectively facing the front surface 21 and the back surface 22 of the base substrate 20 of the to-be-treated substrate 20. Since the lengths of the adjustment arms 532 are adjustable, the positions of the optical inspection device 51 and the pattern making device 52 that are respectively connected to the adjustment arms 532 may be adjusted relative to the to-be-treated substrate 20.

The securing device 54 is used to secure the to-be-treated substrate 20 between the two adjustment arms 532 of the adjustment device 53. The securing device 54 has a suction member 541 that may be one of a vacuum chuck and an electrostatic chuck (E-chuck) to fix the to-be-treated substrate 20 in place via electrostatic force. The securing device 54 allows the to-be-treated substrate 20 to be mounted horizontally or vertically (vertical mounting not shown in the Figures).

It should be noted that shape, patterns and positions of the first alignment pattern 521, the second alignment pattern 522, and the front alignment pattern 31 are not limited to the depiction in the drawings, and may be changed according to practical considerations or processing requirements.

In other embodiments, the geometric center of the front alignment pattern 31 may be overlapped with the geometric center of any one of the first alignment pattern 512 and the second alignment pattern 522.

In other embodiments, the first alignment pattern 512 and the second alignment pattern 522 may be omitted. Instead, the optical inspection device 51 and the pattern making device 52 may be adjusted via a location signal or a pre-calibration process. Alternatively, the optical inspection device 511 may use its own field of view (FOV) as a reference border to align with the front alignment pattern unit 3.

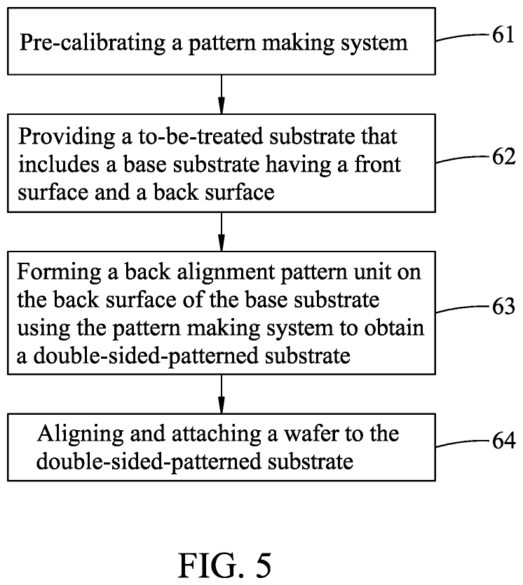

Referring to FIGS. 1, 3 and 5, an embodiment of a method for making the embodiment of the wafer composite structure uses the pattern making system 5 to form the back alignment pattern unit 4 on the back surface 22 of the base substrate 2 of the to-be-treated substrate 20. The embodiment of the method for making the wafer composite structure includes step 61 of pre-calibrating the pattern making system 5, step 62 of providing the to-be-treated substrate 20, step 63 of forming the back alignment pattern unit 4, and step 64 of attaching the wafer (B).

The step 61 of pre-calibrating the pattern making system 5 may be performed with the to-be-treated substrate 20, or may be performed with a calibration substrate. When the step 61 is preformed using the calibration substrate, the step 61 of pre-calibrating the pattern making system 5 may be performed before the step (62).

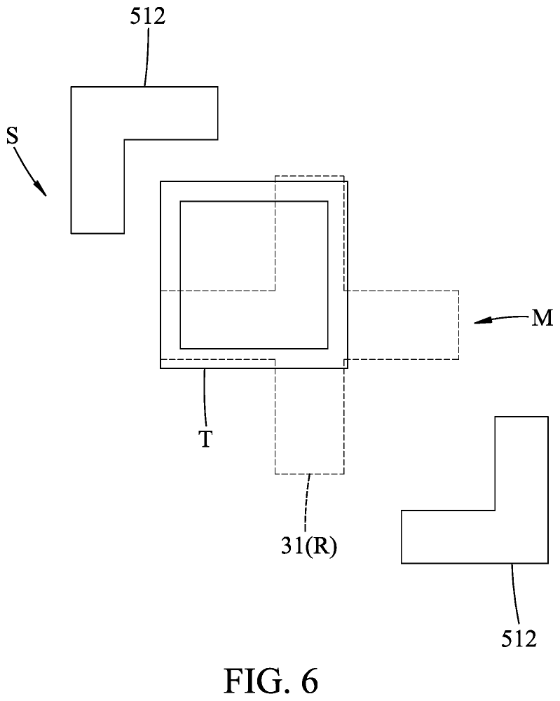

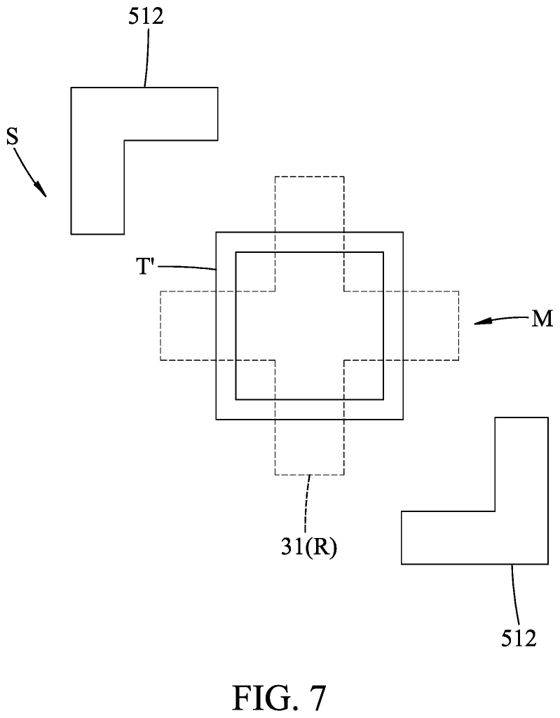

Referring to FIGS. 6 and 7, the step 61 of pre-calibrating the pattern making system 5 includes disposing the optical inspection device 51 and the pattern making device 52 respectively at two opposite sides of a calibration area (S). For example, in this embodiment, the optical inspection device 51 and the pattern making device 52 are respectively located on two opposite sides of the base substrate 2 of the to-be treated substrate 20, and the calibration area (S) is an area of one of the front surface 21 and the back surface 22 of the base substrate 2 (i.e., the base substrate 2 has the calibration area (S)). Then, the position of the optical inspection device 51 and the position of the pattern making device 52 are pre-calibrated according to a first calibrating pattern (R) formed on the calibration area (S) using the adjustment device 53 of the pattern making system 5 so that the position of the optical inspection device 51 and the position of the pattern making device 52 corresponding to the position of the optical inspection device 51 are secured and fixed. It should be noted that the first calibrating pattern (R) may be made via a patterning process or an ablation process. The first calibrating pattern (R) may be formed on the back surface 22 or the front surface 21 on which the front alignment pattern unit 3 is formed. However, as mentioned above, the calibration area (S) may be located at the calibration substrate, and not at the base substrate 2.

In this embodiment, the calibration area (S) is located at the base substrate 2 of the to-be-treated substrate 20, the to-be-treated substrate 20 is a semiconductor substrate, the front alignment pattern unit 3 has a plurality of the front alignment patterns 31, and the first calibration pattern (R) is one of the front alignment patterns 31. In this embodiment, the step 61 of pre-calibrating the pattern making system 5 includes step (d1) to step (d5). In step (d1), the geometric center of the first alignment pattern 512 of the optical inspection device 51 is overlapped with a geometric center of the first calibrating pattern (R) to form an identifying pattern (M) (see FIG. 6) so as to position the optical inspection device 51. In step (d2), a second calibrating pattern (T) (see FIG. 6) is formed in the calibration area (S) with the pattern making device 52. In step (d3), a relative location relationship between the second calibrating pattern (T) and the first calibrating pattern (R) or the identifying pattern (M) is determined whether it is an overlapping relationship where a geometric center of the second calibrating pattern (T) overlaps with a geometric center of the first calibrating pattern (R) or a geometric center of the identifying pattern (M). Afterwards, in step (d4), in the case that it is determined that the geometric center of the second calibrating pattern (T) does not overlap with the geometric center of the first calibrating pattern (R) or the geometric center of the identifying pattern (M), an adjustment process in which the pattern making device 52 is repositioned to form another second calibrating pattern (T′) (see FIG. 7) is initiated, and then, the relative location relationship between the another second calibrating pattern (T′) and the first calibrating pattern (R) or the identifying pattern (M) is determined whether it is in an overlapping relationship. Then, in step (d5), in the case where the geometric center of the another second calibrating pattern (T′) overlaps with the geometric center of the first calibrating pattern (R), the pre-calibrating of the pattern making system 5 is finished. After performing the step 61 of pre-calibrating the pattern making system 5, the optical inspection device 51 and the pattern making device 52 correspond in position relative to a predetermined relation. The aforesaid overlapping relationship may be one in which the geometric centers of the first and second calibrating patterns (R, T) overlap, or the overlapping relationship may be one in which central points measured from borders of an FOV taken from the optical inspection device 51 when the inspection device 51 is aligned with the first and second calibration patterns (R, T) overlap.

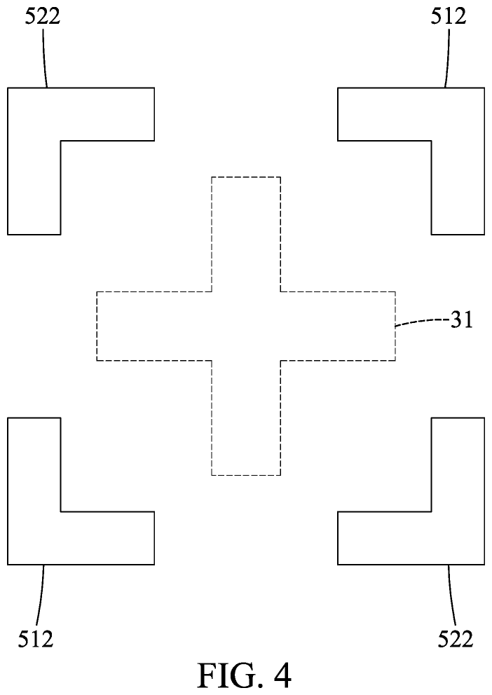

After the step 61 of pre-calibrating the pattern making system 5, the step 63 of forming the back alignment pattern unit 4 is conducted using the pre-calibrated pattern making system 5. In the step 63, the optical inspection device 51 of the pre-calibrated pattern making system 5 is used to obtain a location of the front alignment pattern unit 3 and to generate a location signal. Then, the pattern making device 52 of the pattern making system 5 is used to form the back alignment pattern unit 4 on the back surface 22 of the base substrate 2 of the to-be-treated substrate 20 based on the location signal. After forming the back alignment pattern unit 4 on the back surface 22, a double-sided-patterned substrate (A) is obtained. It should be noted that, the back alignment pattern unit 4 is formed in a predetermined position that corresponds according to a predetermined relation relative to the front alignment pattern unit 3. Referring to FIG. 4, more specifically, the geometric center of the front alignment pattern unit 3 is overlapped with the geometric center of one of the first alignment pattern 512 and the second alignment pattern 522, then the location signal is generated, and the pattern forming member 521 of the pattern making device 52 forms the back alignment pattern unit 4 according to the location signal. For example, in some embodiments, when the geometric center of the first alignment patter 512 overlaps with the geometric center of the back alignment patter unit 4, the location signal of the front alignment pattern unit 3 is generated. In some embodiments, the geometric center of the second alignment pattern 522 of the pattern making device 52 overlaps with the geometric center of the front alignment pattern 31 of the front alignment pattern unit 3, and then the location signal is generated.

In some embodiments, after performing the step 61 of pre-calibrating the pattern making system 5, because the optical inspection device 51 and the pattern making device 52 are already adjusted to correspond in position relative to the predetermined relation, the back alignment pattern unit 4 may be formed directly on the back surface 22 of the base substrate 2 of the to-be-treated substrate 20 based on the location signal. It should be noted that in this case, because the pattern making system 5 is already pre-calibrated, based on the location signal, the pattern making device 52 will not change position before forming the back alignment pattern unit 4.

In the step 64 of attaching the wafer (B), the front alignment pattern unit 3 is aligned with the wafer alignment pattern 11 of the wafer (B) using the position of the back alignment pattern unit 4 as a reference, and the wafer (B) is attached to the front substrate surface 22 of the base substrate 2 of the double-sided-patterned substrate (A) obtained in the step 63, thereby obtaining the wafer composite structure.

However, in some embodiments, the step 61 of pre-calibrating the pattern making system 5 may be omitted. Instead, the geometric center of one of the first alignment pattern 512 of the optical inspection device 51 and the second alignment pattern 522 of the pattern making device 52 is used to overlap with the geometric center of the front alignment pattern 31, and then a location signal is generated. The pattern making member 521 of the pattern making device 52 then forms the back alignment pattern unit 4 based on the location signal. In this embodiment, the pattern making device 52 is adjusted to correspond in position relative to a predetermined relation to the position of the optical inspection device 51 based on the location signal, and then forms the back alignment pattern unit 4. In some embodiments, the pattern making member 52 may be replaced by another optical inspection device (not shown), to form a testing system that can be used to inspect alignment of the wafer composite structure.

In summary of the above, by virtue of the double-sided-patterned substrate (A) including the back alignment pattern unit 4 that has a position corresponding according to the predetermined relation relative to the position of the front alignment pattern unit 3, the wafer (B) may be attached to the front surface 21 of the base substrate of the double-sided-patterned substrate (A) using the back alignment pattern unit 4 as a reference, instead of having to use optical inspection equipment to detect the location of the front alignment pattern unit 3 while performing the wafer (B) attachment. In doing so, alignment accuracy between the wafer (B) and the double-sided-patterned substrate (A) may be increased.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A wafer composite structure comprising:
a wafer including a wafer alignment pattern; and
a double-sided-patterned substrate including
a base substrate that has a front surface and a back surface opposite to said front surface,
a circuit pattern unit that is located on said front surface,
a front alignment pattern unit that is located on said front surface, and
a back alignment pattern unit that is located on said back surface and that has a position corresponding according to a predetermined relation relative to a position of said front alignment pattern unit;
wherein said front surface of said base substrate of said double-sided-patterned substrate is attached with said wafer, and said front alignment pattern unit or said back alignment pattern unit is aligned with said wafer alignment pattern of said wafer.

2. The wafer composite structure as claimed in claim 1, wherein said back alignment pattern unit is indented from said back surface.

3. The wafer composite structure as claimed in claim 1, wherein:
said front alignment pattern unit has at least one front alignment pattern;
said back alignment pattern unit has at least one back alignment pattern that corresponds in position to said at least one front alignment pattern; and
a geometric center of said at least one back alignment pattern is situated in a predetermined position that corresponds according to a predetermined relation relative to a position of a geometric center of said at least one front alignment pattern.

4. The wafer composite structure as claimed in claim 1, wherein a geometric center of said back alignment pattern unit overlaps with a geometric center of said front alignment pattern unit.

5. A method for making a wafer composite structure comprising:
a) providing a to-be-treated substrate that includes a base substrate having a front surface and a back surface opposite to the front surface, a circuit pattern unit located on the front surface, and a front alignment pattern unit located on the front surface;
b) forming a back alignment pattern unit on the back surface of the base substrate, the back alignment pattern unit being formed in a predetermined position that corresponds according to a predetermined relation relative to the front alignment pattern unit; and
c) aligning the front alignment pattern unit with a wafer alignment pattern of a wafer using the position of the back alignment pattern unit as a reference, and attaching the wafer to the front substrate surface of the base substrate.

6. The method for making a wafer composite structure as claimed in claim 5, wherein, in the step b) of forming the back alignment pattern unit,
an optical inspection device of a pattern making system is used to obtain a location of the front alignment pattern unit and to generate a location signal; and
a pattern making device of the pattern making system is used to form the back alignment pattern unit on the back surface based on the location signal.

7. The method for making the wafer composite structure as claimed in claim 6, further comprising before step (b):
d) positioning the pattern making system so that the optical inspection device and the pattern making device are respectively located on two opposite sides of a calibration area, and pre-calibrating a position of the optical inspection device and a position of the pattern making device according to a first calibrating pattern located on the calibration area using an adjustment device of the pattern making system so that the position of the optical inspection device and the position of the pattern making device corresponding to the position of the optical inspection device are secured and fixed.

8. The method for making the wafer composite structure as claimed in claim 7, wherein the calibration area is located at a calibration substrate.

9. The method for making the wafer composite structure as claimed in claim 7, wherein the calibration area is located at the base substrate.

10. The method for making the wafer composite structure as claimed in claim 9, wherein:
the front alignment pattern unit has a plurality of the front alignment patterns; and
the pre-pattern is one of the front alignment patterns.

11. The method for making the wafer composite structure as claimed in claim 7, wherein the optical inspection device has a first alignment pattern, and in step d), pre-calibrating the pattern making system is conducted by:
d1) overlapping a geometric center of the first alignment pattern of the optical inspection device with a geometric center of the first calibrating pattern to form an identifying pattern so as to position the optical inspection device;
d2) forming a second calibrating pattern in the calibration area with the pattern making device;
d3) determining whether a relative location relationship between the second calibrating pattern and the first calibrating pattern is an overlapping relationship where a geometric center of the second calibrating pattern overlaps with a geometric center of the first calibrating pattern;
d4) in the case that it is determined that the geometric center of the second calibrating pattern does not overlap with the geometric center of the first calibrating pattern, initiating an adjustment process in which the pattern making device is repositioned and forms another second calibrating pattern, and whether the relative location relationship between the another second calibrating pattern and the first calibrating pattern is an overlapping relationship is determined; and
d5) in the case that the center of geometry of the another second calibrating pattern overlaps with the center of geometry of the first calibrating pattern the pre-calibrating of the pattern making system is finished.

12. The method for making the wafer composite structure as claimed in claim 7, wherein:
the first calibrating pattern is made via a patterning process or an ablation process;
the calibration area is located at one of the front surface and the back surface of the base substrate.

13. The method for making the wafer composite structure as claimed in claim 6, wherein:
the optical inspection device has a first alignment pattern, the pattern making device having a second alignment pattern and a pattern forming member; and
the step b) of forming the back alignment pattern unit includes overlapping a geometric center of the front alignment pattern unit with a geometric center of one of the first alignment pattern and the second alignment pattern before generating the location signal, and the pattern forming member forms the back alignment patter unit according to the location signal.

14. The method for making the wafer composite structure as claimed in claim 5, wherein the to-be-treated substrate is mounted horizontally or vertically.

15. A pattern making system that is adapted to form a back alignment pattern unit on a to-be-treated substrate, the to-be-treated substrate including a base substrate that has a front surface and a back surface opposite to the front surface, and a front alignment pattern unit on the front surface, the back alignment pattern unit to be formed on the back surface of the base substrate of the to-be-treated substrate, said pattern making system comprising:
an optical inspection device adapted to be disposed on the front surface of the base substrate of the to-be-treated substrate, and having a first alignment pattern that has a geometric center, when said geometric center of said first alignment pattern overlaps with a geometric center of the back alignment pattern unit, a location signal of the front alignment pattern unit is generated;
a pattern making device adapted to be disposed on the back surface of the to-be-treated substrate, signally connected to said optical inspection device, and configured to form the back alignment pattern unit on the back surface of the base substrate of the to-be-treated substrate based on the location signal, the back alignment pattern unit and the front alignment pattern unit corresponding in position to each other according to a predetermined relation; and
an adjustment device connected to said optical inspection device and said pattern making device to allow adjustment of positions of said optical inspection device and said pattern making device relative to the to-be-treated substrate, said adjustment device having a securing member, and two adjustment arms that extend from said securing member, and that are respectively connected to said optical inspection device and said pattern making device.

16. The pattern making system as claimed in claim 15, wherein a geometric center of the back alignment pattern unit overlaps a geometric center of the front alignment pattern unit.

17. The pattern making system as claimed in claim 16, wherein said pattern making device has a second alignment pattern that has a geometric center overlapping with a geometric center of a front alignment pattern of the front alignment pattern unit.

18. The pattern making system as claimed in claim 15, wherein said pattern making device includes a pattern making member that is one of a 3D printer, a laser additive manufacturing machine, an electron beam machine, and an ion beam machine.
